(19) United States
(12) Patent Application Publication
(10) Pub. No.: US 2004/0086140 A1
(43) Pub. Date: May 6, 2004

(54) Apparatus and method for driving an audio speaker

(76) Inventors: Stephen John Fedigan, Plano, TX (US); Clifford L. Blodget, Houston, TX (US)

Correspondence Address: TEXAS INSTRUMENTS INCORPORATED, P O BOX 655474, M/S 3999, DALLAS, TX, 75265

(21) Appl. No.: 10/651,366

(22) Filed: Aug. 30, 2003

Related U.S. Application Data
(60) Provisional application No. 60/424,184, filed on Nov. 6, 2002.

(51) Int. Cl. H03G 11/00; H04R 29/00

(52) U.S. Cl. 381/96; 381/59; 381/55

(57) ABSTRACT

An apparatus for driving a speaker that includes an audio element moved by drive signals applied to the speaker, the speaker having a resistance and a force factor, includes: (a) an amplifier generating drive signals and having an output coupled with the speaker and an input; and (b) a feedback circuit coupling the speaker with the input and including: (1) a monitor coupled with the speaker and generating indicating signals representing selected speaker signal parameters; and (2) a processor coupled with the monitor, with the input and with a signal source providing received signals. The processor combines the received signals with the indicating signals to generate a modified signal for use by the amplifier in generating drive signals. The modified signal includes at least one factor relating to velocity of the audio element. Efficiency of the speaker is improved by inversely varying the resistance and the force factor with respect to each other.

This application claims benefit of prior filed copending Provisional Patent Application Serial No. 60/424,184, filed Nov. 6, 2002.

### BACKGROUND OF THE INVENTION

The present invention is directed to loudspeaker systems, and especially to moving coil loudspeaker systems. Moving coil loudspeakers are inefficient devices that may require hundreds of watts of electrical input power to produce just a few watts of acoustical output power. By way of example and not by way of limitation, a typical loudspeaker might have an efficiency of 0.25%, which means that 400 Watts of input power are needed to produce a single watt of output power.

The efficiency of a loudspeaker in its midband operating range may be calculated using the formula:

$${η}_{0} = \frac{{ρ}_{0} {BL}^{2} {S}_{D}^{2}}{2 π {cR}_{E} {M}_{MD}^{2}} \qquad [ 1 ]$$

Where,

ρ₀=Density of air (1.18 kg per cubic meter)

c=Velocity of sound (345 meters per second)

B=Flux density in airgap (Teslas)

L=Length of voice - coil wire in air gap (m)

S_{D}=Diaphram area (meters squared)

R_{E}=DC coil resistance (ohms)

M_{MD}=Moving mass (kilograms); includes diaphraghm or cone mass and mass of voice coil

Expression [1] suggests several possibilities for increasing efficiency.

Increasing the air gap flux density by using a higher strength magnet is attractive because according to the formula, efficiency η₀ increases with the square of flux density B.

Increasing length of the voice coil wire L may be effected, for example, by using finer wire to increase the number of turns of the voice coil exposed to the magnetic field. However, for a given geometry, increasing the number of turns means shrinking the wire diameter, which causes an increase in coil resistance R_{E} which operates to reduce efficiency.

Increasing the surface area S_{D} of the diaphragm has the effect of increasing the diaphragm's moving mass M_{MD}. Because the terms S_{D} and M_{MD} are in the numerator and the denominator of expression [1] there is little affect upon efficiency when either of those terms is changed.

Decreasing the diaphragm mass M_{MD} using lighter materials appears attractive, but it is difficult to find a material much lighter than the high performance impregnated paper cones that are currently being used in speakers today.

Using a higher strength magnet to increase flux density B is the most practical of these choices. FIG. 1 illustrates what happens to the sound pressure level curve when flux density B is increased.

Above and below the diaphragm resonant frequency, the sound pressure level (SPL) increases for the same voltage (and therefore power) input. However, at diaphragm resonance, the SPL diminishes. To understand why this occurs, it is helpful to examine the speaker diaphragm's equation of motion:

$${M}_{MD} {\ddot{x}}_{D} + \{ {R}_{M} + \frac{{( BL )}^{2}}{{R}_{E}} \} {\dot{x}}_{D} + \frac{{x}_{D}}{{C}_{M}} = \frac{( BL ) {e}_{g}}{{R}_{E}} \qquad [ 2 ]$$

Where,

x_{D}=Diaphram displacement (meters)

e_{g}=Amplifier input voltage (volts)

M_{MD}=Moving mass (kilograms)

R_{M}=Suspension damping (newton—seconds per meter)

C_{M}=Suspension compliance (meters per Newton)

B=Flux density in airgap (Telsas)

L=Length of voice - coil wire in air gap (m)

R_{E}=DC coil resistance (ohms)

The BL factor enters into the equation of motion (expression [2]) in two ways. First, BL relates the input voltage to the force applied to the diaphragm. It is for this reason that the term BL is often referred to as the force factor. Second, when the speaker cone is in motion, BL relates cone velocity to back EMF (electromotive force). Back EMF is a voltage e_{b} that creates a negative current in the voice coil winding, which is reflected back to the mechanical system of the speaker as a force proportional to velocity of the cone. Back EMF e_{b} is seen by the speaker cone as a damper. This “electronic” damping diminishes the acoustic response curve (FIG. 1) at resonance and results in a poor bass response.

It is known in the art that loudspeakers become more efficient as the total magnetic flux B is increased. See Abstract; Vanderkooy and Boers, “High Efficiency Direct-Radiator Loudspeaker Systems”, Audio Engineering Society Convention Paper 5651, October 5-8, 2002, Los Angeles, Calif. However, when force factor BL is substantially increased, the acoustic output is no longer even reasonably flat and equalization must be used. See page 2, Column 1; Vanderkooy and Boers (emphasis in original).

According to commonly accepted wisdom in prior art loudspeaker theory, there is no increase in low frequency amplitude with increased force factor BL because at the resonant frequency of the diaphragm or around resonance there is electromechanical coupling restricting the moving mass (i.e., the diaphragm mass MMD) from oscillating freely. This condition is referred to in prior art as being overdamped.

There is a need for an apparatus and method for driving an audio loudspeaker that increases acoustic efficiency without requiring equalization or other adjusting treatment of the speaker output.

There is a need for an apparatus and method for driving an audio loudspeaker that will not overdamp the speaker system.

### SUMMARY OF THE INVENTION

An apparatus for driving a speaker that includes an audio element moved by drive signals applied to the speaker, the speaker having a resistance and a force factor, includes: (a) an amplifier generating drive signals and having an output coupled with the speaker and an input; and (b) a feedback circuit coupling the speaker with the input and including: (1) a monitor coupled with the speaker and generating indicating signals representing selected speaker signal parameters; and (2) a processor coupled with the monitor, with the input and with a signal source providing received signals. The processor combines the received signals with the indicating signals to generate a modified signal for use by the amplifier in generating drive signals. The modified signal includes at least one factor relating to velocity of the audio element. Efficiency of the speaker is adjusted by inversely varying the resistance and the force factor.

A method for controlling driving of an audio speaker device including an audio element; the speaker device being driven by electrical drive signals applied at a speaker input locus to effect sound-producing movement by the audio element, the speaker device having a resistance and a force factor, includes the steps of: (a) in no particular order: (1) providing an amplifier unit having an amplifier input locus and an amplifier output locus; the amplifier output locus being coupled with the speaker input locus for applying the electrical drive signals; and (2) providing a feedback circuit coupling at least one of the amplifier output locus and the speaker input locus with the amplifier input locus; the feedback circuit including: [a] a monitoring unit coupled with at least one of the amplifier output locus and the speaker input locus; and [b] a processing unit coupled with the monitoring unit, with an input locus of the amplifier unit and with a signal source providing input signals representative of an audio input; (b) operating the amplifier unit to generate the electrical drive signals; (c) operating the monitoring unit to generate indicating signals representing selected parameters associated with signals present at the speaker input locus; (d) operating the processing unit to combine the input signals with the indicating signals to generate a modified input signal for use by the amplifier unit in generating the electrical drive signals; the modified input signal including at least one factor relating to velocity of the audio element while effecting the sound-producing movement; and (e) adjusting efficiency of the speaker device by inversely varying the resistance and the force factor It is, therefore, an object of the present invention to provide an apparatus and method for driving an audio loudspeaker that increases acoustic efficiency without requiring equalization or other adjusting treatment of the speaker output.

It is a further object of the present invention to provide an apparatus and method for driving an audio loudspeaker that will not overdamp the speaker system.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is a graphic plot illustrating changes in sound pressure level of prior art audio speaker as a function of frequency for selected force factors BL.

FIG. 2 is a graphic plot illustrating the effect upon sound pressure level of an audio speaker as a function of frequency using the apparatus of the present invention and adjusting scaling factor r.

FIG. 3 is a schematic diagram of the apparatus of the present invention.

FIG. 4 is a flow diagram illustrating the method of the present invention.

### DETAILED DESCRIPTION OF THE PREFERRED EMBODIMENT

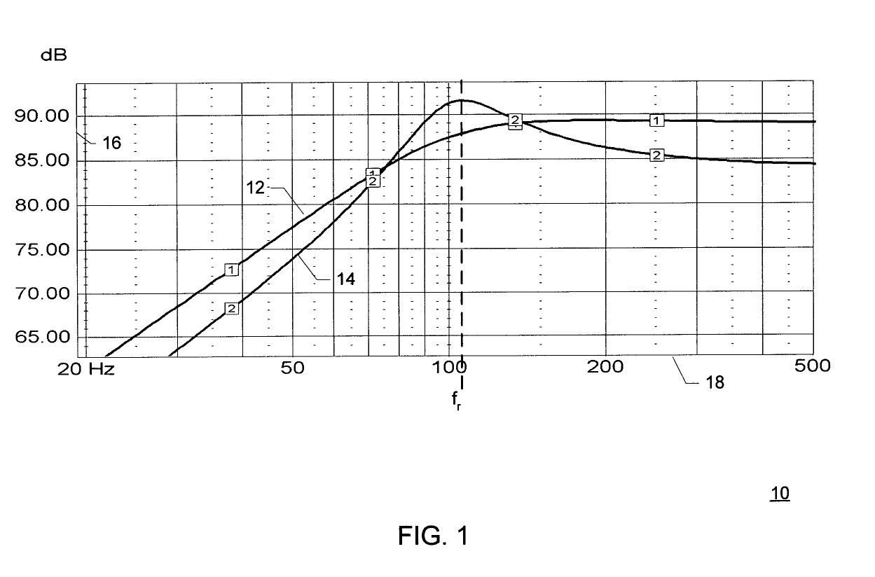

FIG. 1 is a graphic plot illustrating changes in sound pressure level of a prior art audio speaker as a function of frequency for selected force factors BL. In FIG. 1, a graphic plot 10 illustrates a first curve 12 representing a first sound pressure level (SPL) response and a second curve 14 representing a second SPL response. SPL response curves 12, 14 are measured according to decibels (dB) indicated on a first axis 16 as a function of frequency measured according to Hertz (Hz) indicated using a logarithmic scale on a second axis 18. First SPL response curve 12 illustrates response of a speaker having a relatively high force factor BL. First SPL response curve 12 substantially smoothly transitions from lower frequencies to higher frequencies passing through the resonant frequency of the speaker diaphragm fᵣ with little discernible deviation. In contrast, second SPL response curve 14 exhibits a discernible deviation, or peak, at resonant frequency fᵣ, thereby demonstrating the effect of increasing force factor BL in a prior art speaker. Increasing force factor BL increases SPL for most similar frequencies—a benefit. However, increasing force factor BL also causes SPL to diminish at resonant frequency fᵣ—an undesirable result.

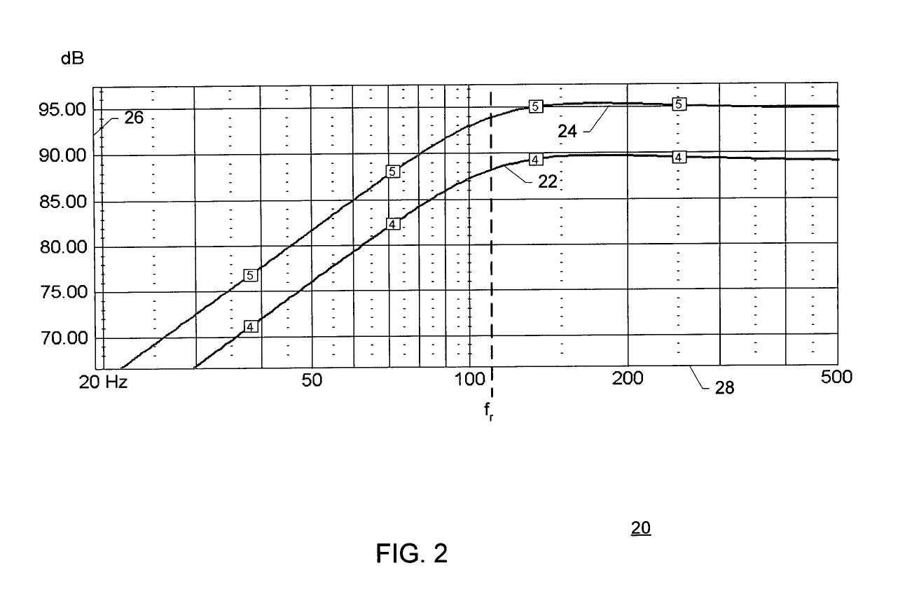

FIG. 2 is a graphic plot illustrating the effect upon sound pressure level of an audio speaker as a function of frequency using the apparatus of the present invention and adjusting scaling factor r. In FIG. 2, a graphic plot 20 illustrates a first curve 22 representing a first sound pressure level (SPL) response and a second curve 24 representing a second SPL response measured according to decibels (dB) indicated on a first axis 26 as a function of frequency measured according to Hertz (Hz) indicated using a logarithmic scale on a second axis 28. First SPL response curve 22 illustrates response of a prior art speaker having an appropriate force factor BL and other design aspects to establish a substantially smooth transition from lower frequencies to higher frequencies passing through the resonant frequency of the speaker (i.e., of the speaker diaphragm) fᵣ with little discernible deviation. Second SPL response curve 24 illustrates response of a speaker employing the apparatus and method of the present invention. Second SPL curve 24 exhibits increased SPL for similar frequencies as compared with first SPL response curve 22 with no reduction in SPL around resonant frequency fᵣ.

To correct overdamping, one may add a signal to the original amplifier input which is proportional to the cone velocity. Adding a velocity factor Kᵥ\dot{x}_{D} to expression [2] permits description of the positive velocity feedback structure and operation of the present invention:

$${M}_{MD} {\ddot{x}}_{D} + \{ {R}_{M} + \frac{{( BL )}^{2}}{{R}_{E}} \} {\dot{x}}_{D} + \frac{{x}_{D}}{{C}_{M}} = \frac{BL}{{R}_{E}} \{ {e}_{g} + {K}_{v} {\dot{x}}_{D} \} \qquad [ 3 ]$$

Note that the term {e_{g}+K_{V}\dot{x}_{D}} is a voltage term related to velocity \dot{x}_{D}.

Where,

$${\dot{x}}_{D} is \frac{ⅆ {x}_{D}}{ⅆ t} ,$$

velocity of the cone.

If we define

Kᵥ≡rBL [4]

where r is a scaling factor that ranges in value from 0 to 1, we can move the voltage-related-to-velocity term rBL \dot{x}_{D} to the left hand side of expression [4] and combine terms as follows:

$${M}_{MD} {\ddot{x}}_{D} + \{ {R}_{M} + \frac{{( BL )}^{2}}{{R}_{E}} ( 1 - r ) \} {\dot{x}}_{D} + \frac{{x}_{D}}{{C}_{M}} = \frac{BL}{{R}_{E}} {e}_{g} \qquad [ 5 ]$$

The term

$$[ \frac{{( BL )}^{2}}{{R}_{E}} {\dot{x}}_{D} ] \qquad [ 6 ]$$

represents systemic damping by the speaker system that is manifested by a force resisting movement of the speaker cone in response to applying voltage e_{g} to the amplifier input. The term

$$[ - r \frac{{( BL )}^{2}}{{R}_{E}} {\dot{x}}_{D} ] \qquad [ 7 ]$$

represents electronic damping that may be applied to a speaker system by varying BL or R_{E} or both BL and R_{E}, as scaled by scaling factor r. This is so because, the term rBL \dot{x}_{D} is a voltage (see expression [3]), and multiplying a voltage by the quantity

$$\frac{BL}{RE}$$

yields a force that is related to cone velocity (\dot{x}_{D}). That is, the quantity BL relates electrical current to a physical force through the mechanism of the magnetic field having a magnetic strength B. Relating force to a voltage establishes expression [7] as an electronically controllable damping factor.

Expression [7] demonstrates that one may electronically control system damping. If we select the proper value for scaling factor r, system damping can be restored to a desirable level, as illustrated in FIG. 2 (second SPL response curve 24). The negative sign associated with expression [7] indicates that it is a positive feedback term because it positively affects systemic damping as set forth in expression [6] (i.e., no sign change is required to positively affect systemic damping). Using such a positive velocity feedback technique, one can construct an efficient transducer having a desirable SPL (sound pressure level) response.

As mentioned earlier herein, back EMF e_{b} is related with cone velocity:

e_{b}=BL\dot{x}_{D} [8]

Back EMF e_{b} may be expressed in terms related to a feedback voltage e_{f}, where:

e_{f}=rBL\dot{x}_{D} [9]

Thus, feedback voltage e_{f} is directly proportional to back EMF e_{b}, which can be calculated using the following relationship:

e_{b}=e_{g}−i_{C}R_{E}=BL\dot{x}_{D} [10]

By measuring the voltage across the speaker terminals e_{g} and current through the voice coil i_{c}, and by knowing the winding resistance R_{E} of the voice coil one can determine cone velocity \dot{x}_{D} and thereby ascertain feedback voltage e_{f} without having to embed an expensive (and potentially unreliable) sensor in the speaker.

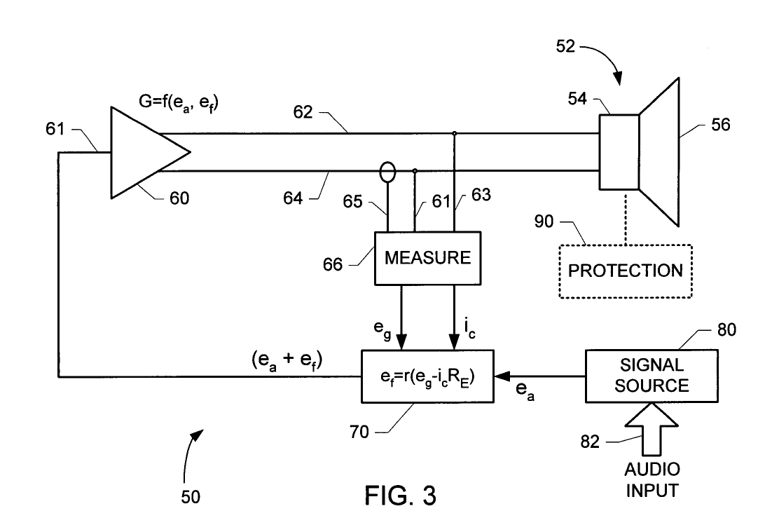

FIG. 3 is a schematic diagram of the apparatus of the present invention. In FIG. 3, a drive apparatus 50 is configured and connected for driving a speaker 52. Speaker 52 includes a voice coil 54 coupled with a speaker cone or diaphragm 56. Details of the coupling between voice coil 54 and cone 56 are not illustrated in FIG. 3. Drive apparatus 50 includes an amplifier 60 for applying a drive signals to speaker 52 via signal lines 62, 64. A measuring or monitoring unit or device 66 is coupled with signal lines 62, 64 to measure at least one selected parameter associated with signals traversing signal lines 62, 64. Preferably, as indicated in FIG. 3, measuring unit 66 measures voltage e_{g} across terminals of speaker 52 and current i_{c} through voice coil 54. As mentioned earlier herein, by measuring the voltage e_{g} across the speaker terminals and current i_{c} through the voice coil, and by knowing the winding resistance R_{E} of voice coil 54 one can determine cone velocity \dot{x}_{D} and thereby use expressions [9] and [10] to ascertain feedback voltage e_{f}.

A processing unit or device 70 is coupled with measuring unit 66 and receives indicating signals from measuring unit 66 conveying values for the at least one selected parameter measured by measuring unit 66. Processing unit 70 also receives an input signal eₐ from a signal source 80. Signal eₐ is an electrical signal representing an input received by signal source 80, such as an audio input 82. Audio input 82 may be received from any of a variety of audio input devices, such as a microphone or other device (not shown in FIG. 3).

Processing unit 70 calculates feedback voltage e_{f} substantially according to expressions [8] and [9]. Processing unit 70 combines input signal eₐ with feedback voltage e_{f} and provides that combined signal (eₐ+e_{f}) to an input locus 61 of amplifier 60. The positive combining of voltages eₐ and e_{f} reinforces that drive apparatus 50 is a positive velocity feedback system. Amplifier 60 imparts a gain G to signals arriving at input locus 61 to generate drive signals for application to speaker 52 via signal lines 62, 64. Gain G is a function of input signal eₐ and feedback voltage e_{f}, as indicated in FIG. 3. Accordingly, drive signals traversing signal lines 62, 64 involve a factor related with velocity of cone 56, as discussed earlier herein in connection with expression [8]. Thus, processing unit 70 estimates the velocity of cone 56, calculates a feedback signal mixing factors relating to the velocity of cone 56 and input signal eₐ, and provides that modified signal (eₐ+e_{f}) to amplifier 60. Thus drive apparatus 50 is a positive velocity compensation feedback circuit.

Drive apparatus 50 has been implemented by the inventors with processing unit 70 embodied in a digital signal processor (DSP) for estimating cone velocity \dot{x}_{D}, calculating feedback voltage e_{f}, mixing feedback voltage e_{f} with input signal ea, and sending the mixed or modified feedback signal (e_{f}+eₐ) to input 61 of amplifier 60.

One result of using drive apparatus 50 is that voltage level gain G in signals applied to speaker 52 increases over speaker devices not employing drive apparatus 50. This result may be seen using expression [3] and solving for cone velocity:

$$\frac{{U}_{D} ( s )}{{E}_{a} ( s )} = \frac{( BL / {R}_{E} ) s}{{M}_{MD} {s}^{2} + \{ {R}_{M} + ( 1 - r ) {BL}^{2} / {R}_{E} \} s + 1 / {C}_{M}} \qquad [ 11 ]$$

Where

$$s = \frac{ⅆ}{ⅆ t}$$

and

U_{D}(S)/Eₐ(S) is a transfer function from amplifier input voltage to cone velocity.

Since feedback voltage e_{f} is proportional to cone velocity \dot{x}_{D}, according to expression [9], the transfer function from amplifier voltage to feedback voltage is:

$${E}_{f} ( s ) = {rBLU}_{D} ( s ) ⇒ \frac{{E}_{f} ( s )}{{E}_{a} ( s )} = \frac{( {rBL}^{2} / {R}_{E} ) s}{{M}_{MD} {s}^{2} + \{ {R}_{M} + ( 1 - r ) {BL}^{2} / {R}_{E} \} s + 1 / {C}_{M}} \qquad [ 12 ]$$

The total amplifier input voltage is the sum of the amplifier input voltage ea and feedback voltage e_{f}, the transfer function of which can be written as:

$${E}_{t} ( s ) = {E}_{a} ( s ) + {E}_{f} ( s ) ⇒ \frac{{E}_{t} ( s )}{{E}_{a} ( s )} = \frac{{M}_{MD} {s}^{2} + \{ {R}_{M} + {BL}^{2} / {R}_{E} \} s + 1 / {C}_{M}}{{M}_{MD} {s}^{2} + \{ {R}_{M} + ( 1 - r ) {BL}^{2} / {R}_{E} \} s + 1 / {C}_{M}} \qquad [ 13 ]$$

The material damping is negligible as compared with the electronic damping, so one can write the approximate expression:

$$\frac{{E}_{t} ( s )}{{E}_{a} ( s )} \approx \frac{{M}_{MD} {s}^{2} + \{ {BL}^{2} / {R}_{E} \} s + 1 / {C}_{M}}{{M}_{MD} {s}^{2} + \{ ( 1 - r ) {BL}^{2} / {R}_{E} \} s + 1 / {C}_{M}} \qquad [ 14 ]$$

From expression [14], at frequencies significantly above and below resonance (frequency fᵣ; FIGS. 1 and 2), very little additional amplifier supply voltage is required. However, at or near resonance, the supply voltage magnification required is approximately:

$$\frac{{E}_{t} ( j {ω}_{n} )}{{E}_{a} ( j {ω}_{n} )} \approx \frac{1}{1 - r}$$

The additional amplifier headroom that is required depends on the feedback ratio (scaling factor) r. This becomes particularly important for high BL speakers where r approaches 1. For typical values of r=0.50 to 0.75, the headroom is anywhere from 2× to 4× its original value. Such additional headroom requires a higher amplifier power supply voltage, which causes greater RFI/EMI (radio frequency interference/electromagnetic interference) in switching supplies and class D amplifiers and requires more expensive power supply components such as bus capacitors. There is also a practical limit to how high supply voltage can go as one considers available switching transistors and safety concerns.

To address this voltage overhead problem, suppose we reduce R_{E} and adjust BL according to the ratio:

$${BL}_{2} = {BL}_{t} \sqrt{( {R}_{E2} / {R}_{E1} )} \qquad [ 16 ]$$

where BL₂ and R_{E2} are the new values and BL₁ and RE₁ are the originals.

Thus, solving expression [16] for R_{E2}:

$${R}_{E2} = \frac{{BL}_{2}^{2} \cdot {R}_{e1}}{{BL}_{1}^{2}} \qquad [ 17 ]$$

Expression [16] is arrived at by using expression [1] using a first such expression relating to a first BL₁ and a second such expression relating to a second BL₂ expressed in a ratio

$$\frac{{BL}_{2}}{{BL}_{1}}$$

to determine what new BL₂ may be attained by adjusting coil resistance R_{E} without changing efficiency η₀. Because all other factors in the numerator and denominator remain unchanged (in order to keep efficiency η₀ constant), expression [16] results.

Because BL is diminished (i.e. BL₂<BL₁), the pressure sensitivity at resonance increases. This is apparent when one inspects the formula relating to pressure sensitivity at resonance:

$$\frac{p ( j {ω}_{s} )}{{E}_{g} ( {jω}_{s} )} \approx \frac{{ρ}_{0}}{2 π {S}_{D} {M}_{AS} BL} \sqrt{\frac{{M}_{MD}}{{C}_{M}}} \qquad [ 18 ]$$

where p(jωₛ) expresses pressure at the resonant frequency ωₛ; j=\sqrt{−1};

E_{g} (jωₛ) expresses amplifier input voltage e_{g} at the resonant frequency ωₛ; and

M_{AS} is the acoustical mass of the system (i.e., generally, the mass of the voice coil, plus mass of the speaker cone, plus mass of the coil suspension components, plus mass of the air moved by the cone).

Thus, by adjusting R_{E} and BL according to expression [16], BL may be increased to a lesser value to achieve a given increase in efficiency η₀ than has been previously required. Expression [18] establishes that a lesser value for BL requires a lesser input voltage e_{g} (at the expense of greater coil current i_{C}) to achieve the same sound pressure levels, thus offsetting the increased voltage overhead created by the positive feedback loop. This is so because both terms BL and E_{g}(jω) are in the denominator of expression [18], so terms BL and E_{g}(jω) will vary together. A further advantage to reducing voltage E_{g}(jω) and increasing voice coil current i_{C} (because of reduced recoil resistance R_{E}) is realized in that higher current components are generally less expensive and in some cases less bulky than high voltage components.

The inventors have found that by using thicker wire, voice coil resistance R_{E} is reduced and the same sound pressure levels (SPLs) can be produced with lower voltages e_{g} at the expense of higher voice coil currents i_{C}. The result is that the absolute peak of voltage e_{g} at resonance is reduced even though speaker gain is the same.

Resonance plays a very large role in the function of prior art low frequency loudspeakers in sealed box and ported box configurations. This is the case because the majority of the power that is consumed by a prior art loudspeaker is dissipated in heat associated with oscillating the moving mass (i.e., the speaker cone) and not converted into acoustic output. To reduce the power required to oscillate the moving mass a mechanical or acoustic spring component has been added so that the moving mass will have a propensity to oscillate at a low frequency thereby reducing the power required to achieve a given amplitude or excursion. Such mechanical or acoustic spring components result in a large increase in speaker output at the resonant frequency (fᵣ; FIGS. 1 and 2) and to a lesser degree at frequencies surrounding the resonant frequency. In prior art loudspeakers the power required to achieve a given amplitude at resonance is significantly lower than power required to achieve a similar amplitude at frequencies other than the resonant frequency. It is for this reason that prior art speaker devices place the resonant frequency in the lower part of the frequency range of concern where loudspeakers tend to be least efficient. As a result a prior art loudspeaker is more efficient at its resonant frequency than at other frequencies, but is relatively inefficient at all frequencies.

In the present invention force factor BL is increased (the increase in BL increases back EMF e_{b}) so that less power is required to oscillate the mass (i.e., M_{MD}, diaphragm mass) to a given amplitude. Because less power is required to oscillate the moving mass, dependence on the resonant effect and the effect of the spring component (mechanical or acoustic) to boost amplitude is reduced. As force factor BL is increased the efficiency at the frequencies substantially above and below resonant frequency fᵣ increase at a constant rate while at and immediately around resonant frequency fᵣ the efficiency does not increase until the total BL increase is greater than the amount of boost to the output contributed by the resonant effect of the mechanical or acoustic spring force (or, if applicable, the resonant effect of both mechanical and acoustic spring forces).

The commonly accepted wisdom in prior art loudspeaker theory and design is that if the electromotive force (EMF; i.e., drive voltage e_{g}) or force factor BL of a loudspeaker is increased, speaker efficiency at low frequencies will not increase. This has been regarded to be the result of the back EMF e_{b} increasing and counteracting the drive voltage e_{g} from the amplifier negating any gain in usable output from the loudspeaker.

In the present invention force factor BL is increased and voice coil resistance R_{E} is decreased significantly. This novel combination results in much higher efficiency than has been achieved in prior art speaker devices and produces improved output at all frequencies. The negative impact of back EMF e_{b} or overdamping phenomena and the associated decrease in speaker output at low frequencies with increased force factor BL that is cited in prior art theory and practice is not a problem when employing the apparatus and method of the present invention because thermal losses are lower than is experienced with prior art devices that only increase force factor BL. Power that is converted to acoustic energy is much greater using the apparatus and method of the present invention.

The apparatus and method of the present invention may be described using a new design paradigm:

Power consumed=(power transferred to the moving mass−power recaptured from the moving mass)+(power transferred to the acoustic load power recaptured from the acoustic load)+thermal dissipation losses in the voice coil+thermal dissipation losses in the mechanical components

Using the apparatus and method of the present invention, increased back EMF e_{b} and overdamping do not limit low frequency speaker output because the resonant boost so heavily relied upon in prior art is effectively swamped by the increase in force factor BL and the increase in efficiency.

Back EMF voltage=amplifier output voltage−(voltage applied to mechanical load+voltage applied to resistive losses)

Using the apparatus and method of the present invention, if force factor BL or electromotive force e_{g} is increased at the same time voice coil resistance R_{E} is decreased then the voltage applied to resistive losses decreases as the back EMF e_{b} increases and the voltage applied to the mechanical load increases. Reducing coil resistance R_{E} has not heretofore been viewed as a benefit in speaker design. Such a design measure is not necessary unless one significantly increases magnetic flux density B. Recent designs seeking to increase efficiency in speaker systems have led to increased levels of magnetic flux density B with a resulting increased back EMF e_{b}. The inventors have discovered that a combination of increasing magnetic flux density B and reducing coil resistance R_{E} achieves increased efficiency while limiting increase in back EMF e_{b}.

Terminal velocity is the velocity at which the voice coil reaches a speed at which back EMF voltage e_{b} is approximately equal to amplifier voltage e_{g}. In prior art loudspeakers most of the power consumed is in the form of thermal loss incurred accelerating and decelerating the moving mass (i.e., MMD, diaphragm mass). Back EMF e_{b} is low because force factor BL is low and the voice coil does not approach terminal velocity. Back EMF e_{b} is highest at resonance where the voice coil is closest to terminal velocity. Using the apparatus and method of the present invention, force factor BL and electromotive force e_{g} are high so that far less power is consumed by thermal losses incurred accelerating and decelerating the moving mass M_{MD}. Back EMF e_{b} is high because force factor BL or electromotive force e_{g} is high and the voice coil approaches terminal velocity much more often at all operational frequencies than occurs in prior art speakers.

Acoustic power=Amplifier output−(back EMF+thermal losses)

Using the apparatus and method of the present invention, if magnetic flux density B is increased a great amount over levels employed in prior art speakers, a significantly higher electromotive strength and force factor BL results. If the transducer is in free air (acoustically unloaded) the high electromagnetic coupling thus established will result in lower power consumption at low audio frequencies. For example, if such an improved transducer is driven with a sine wave less than 150 Hz, the voice coil will be able to track the amplifier signal almost at terminal velocity and the back EMF voltage e_{b} will therefore almost equal the amplifier output voltage e_{g}. At low frequencies the voice coil inductance is small and can be ignored:

Power consumed=(amplifier voltage−back EMF voltage)²/R_{E}

Power consumed=power dissipated in heat+power converted into acoustic output

In the case described earlier hereinabove, where the transducer is in free air and acoustically unloaded at low frequencies, very little of the power goes to acoustic output and essentially all of the power that is consumed is dissipated as heat. If the transducer is mounted in a properly sized box it will be acoustically coupled to the surrounding air (sometimes referred to as “acoustically loaded”). In such an acoustically loaded configuration, a portion of the power that is consumed goes to acoustic output, and a portion of the power that is consumed goes to thermal dissipation.

As a result of the increased efficiency of the present invention over prior art, the use of regenerative braking of the moving mass becomes practical. In prior art only a small fraction of the input power is actually transferred or converted into kinetic energy—so small an amount that the reclamation of this energy was regarded as pointless. Using the apparatus and method of the present invention, high enough conversion efficiencies and motor/generator actions are achievable to make reclaiming the kinetic energy transferred to the moving mass worthwhile, resulting in further-improved performance.

In prior art loudspeakers, the usable excursion of a speaker cone is defined as X-max. Typically, X-max is defined as the distance that a speaker cone or diaphragm can travel before its associated voice coil leaves the magnetic gap of the speaker. In most prior art loudspeakers X-max is the maximum functional excursion possible by a voice coil for various reasons. An important reason is that once the voice coil leaves the magnetic gap the power dissipation capability is drastically reduced because of loss of the thermal path to the gap while the coil is out of the gap. X-mech is a parameter indicating the maximum diaphragm excursion that a loudspeaker can sustain before mechanical damage to the speaker occurs. In prior art loudspeakers X-mech must be set to about double the distance of X-max because the electromechanical coupling in a prior art loudspeakers is so weak that the motion of the cone is not under complete control of the amplifier but is rather just “excited” into motion by the amplifier. Because of this lack of control, a designer must leave excursion headroom. The need for excursion headroom results in an inability to utilize the maximum travel capability of the loudspeaker for controlled output. Using the apparatus and method of the present invention, X-max can be set very close to X-mech because there is much greater control of the travel of the cone while operating a speaker.

By providing a high magnetic strength, low resistance speaker coupled to a positive velocity feedback controller, the inventors have achieved a high efficiency speaker with a desirable voltage sensitivity curve and which requires only a small amount of additional supply voltage.

This high efficiency speaker can be configured to reduce cost, increase acoustical output, reduce enclosure size or any combination of reducing cost, increasing acoustical output and reducing enclosure size,.

By utilizing a low resistance voice coil to counteract the increased back EMF voltage e_{b} due to the high magnetic strength (as opposed to raising the amplifier output voltage) the apparatus and method of the present invention permit configuration of a speaker that is voltage-compatible with present (prior art) amplifier technologies, both analog and digital. It should be noted that while 70 volt to 100 volt power supply rails in conventional prior art high power amplifiers may possibly be doubled, the practical limit is quickly reached in such prior art designs. In contrast, the present invention provides a practical limit to reducing voice coil resistance that is significantly greater in design range than is available for varying supply rails in prior art speakers.

The apparatus and method of the present invention can be employed to advantage in low voltage applications such as battery powered devices, portable devices and automotive applications.

Increased operating efficiency over prior art designs provided by the apparatus and method of the present invention reduces heat in the voice coil and reduces the effects of what is known in the art as thermal compression—the reduced output of a loudspeaker due to heating of the voice coil and the increase in resistance of the voice coil at elevated temperatures.

In addition to the efficiency advantages of the apparatus and method of the present invention, there are acoustic advantages. For example, because of the increased electromechanical coupling provided by the present invention, the speaker cone tracks the amplifier input voltage with greater fidelity.

In prior art speakers, the implementation of servo control and closed loop operation come at a high price because the electromechanical coupling is weak. That is, the motion of the cone is not well correlated to the amplifier output, so the amount of correction required is great, and the power used for correction is great. Using the apparatus and method of the present invention, electromechanical coupling is significantly higher so correlation between motion of the cone and amplifier output is much improved over prior art designs. As a result, servo control becomes more practical because the correction that is applied yields greater and more accurate results.

The present invention has been found to have approximately 3 db to 5 db more usable output for the same maximum mechanical excursion limit (X-mech) over prior art loudspeakers. For example a prior art speaker with an X-max of 10 mm would typically have an X-mech of 20 mm or more to allow for uncontrolled movement of the cone during normal operation. The ratio of X-max/X-mech is typically 0.5 or less in prior art loudspeakers. For such a 50% de-rating of excursion the loss of acoustic output is 6 db. Using the present invention the ratio of X-max/X-mech can be approximately 0.8, giving an X-max of 16 mm for an X-mech of 20 mm and generating 4 db of additional output.

The apparatus and method of the present invention permit increased power handling because of decreased heating of the voice coil. This is a result of the voice coil staying in the magnetic gap a greater amount of the time as compared with prior art speakers because of the increased electromotive coupling and control afforded by the high force factor BL configuration. When the voice coil is allowed to leave the magnetic gap during high output operation, as it does in prior art loudspeakers, the coil no longer cuts the magnetic lines of flux and therefore loses the back EMF voltage e_{b} that opposes the amplifier voltage e_{g}, thereby dramatically increasing current i_{C} through the coil. Without such reduction in current i_{C} through the coil the full value of the voice coil resistance R_{E} is across the amplifier 60 (FIG. 3) so the coil conducts a higher current i_{C} and therefore dissipates more heat.

It is common practice in the loudspeaker industry to test, rate, model, specify, design and otherwise regard loudspeaker performance in terms of voltage sensitivity. As an example, most formulas and software programs used to design loudspeaker systems give the designer a choice of two modes: SPL at 1 meter with 2.83 volts input or SPL at 1 meter with 1 watt input power. In reality the power mode that specifies 1 watt is really not 1 watt at all but is based on an input voltage that would result in 1 watt consumption if the nominal impedance of the loudspeaker was a purely resistive load. In actuality a loudspeaker load on an amplifier does vary with frequency and other conditions so this voltage sensitivity method of measuring loudspeaker acoustic output and power consumption is inaccurate.

Based on the voltage sensitivity models, it is widely indicated in the loudspeaker prior art that there is an optimum point for magnet strength and force factor BL in a loudspeaker where maximum bass efficiency is obtained from a closed box or vented box speaker system. Below that supposed optimum point more acoustic output can be generated for a given input power by increasing magnetic flux B or force factor BL. After that supposed optimum point is reached additional increases in magnetic flux B or force factor BL will not yield additional acoustic output. In conventional terminology the system with more magnetic strength or force factor BL than needed is over damped.

Power sensitivity as defined in the present invention is the actual acoustic output at a frequency for 1 watt of continuous input power that may be calculated or measured over a frequency band to create a power sensitivity curve.

Unlike voltage sensitivity, the inventors have found that an increase of force factor BL increases the power sensitivity of a speaker for the entire frequency range (including resonance). In addition, the inventors have concluded that there is no optimum force factor BL. In other words, power sensitivity will continuously improve as force factor BL is increased.

The apparatus and method of the present invention contemplate raising the force factor BL and simultaneously reducing resistance R_{E} of coil 54 (FIG. 3) of a speaker apparatus. In such a configuration, the low impedance presented by R_{E} may be a problem in some circumstances. For example, if the speaker cone or diaphragm were stalled or obstructed in some way, impedance would drop to R_{E}, which could cause overheating in the voice coil winding or could cause amplifier failure. To avoid such adverse consequences, a protection circuit 90 (FIG. 3) may be added to estimate the temperature of voice coil 54 based on voice coil voltage and current. Protection circuit 90 is illustrated in FIG. 3 in dotted line format to indicate that protection circuit 90 is an optional element of drive apparatus 50. If the temperature of voice coil 54 exceeds a first preset threshold, protection circuit 90 may operate to shut down amplifier 60 until the temperature of voice coil 54 drops below a second preset threshold. Protection circuit 90 preferably includes a thermal model of voice coil 54 (not shown in FIG. 3) executed in real-time. A preferred embodiment of an element for performing such thermal modeling is a digital signal processor (DSP).

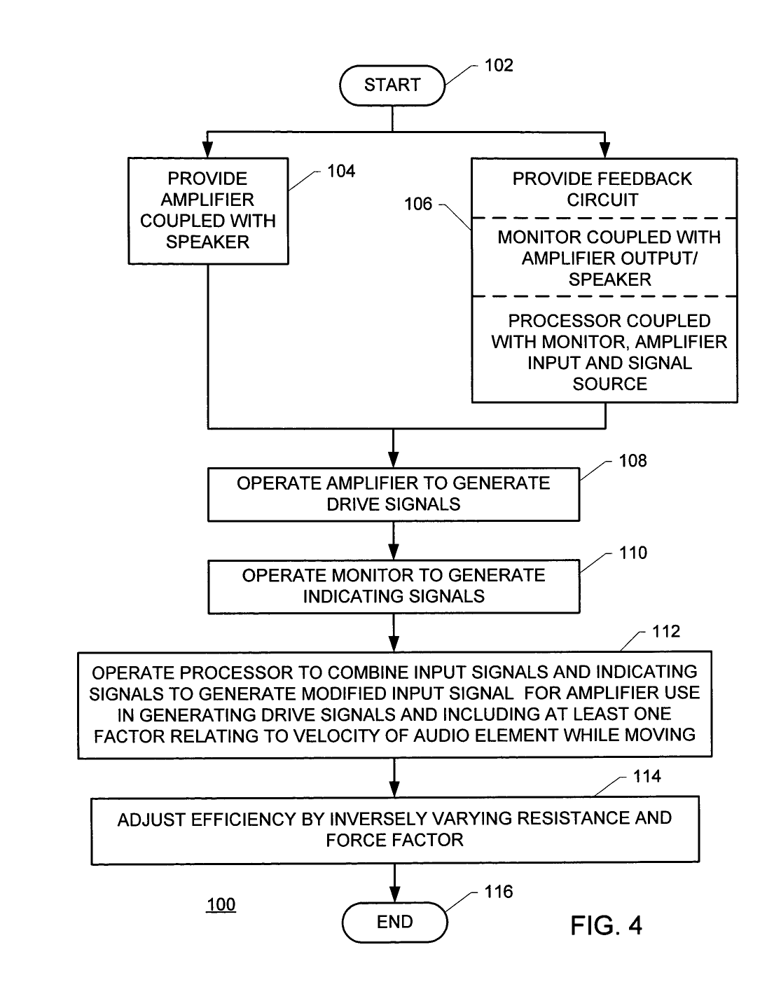

FIG. 4 is a flow diagram illustrating the method of the present invention. In FIG. 4, a method 100 for controlling driving of an audio speaker device begins at a START locus 102. The speaker device includes an audio element and is driven by electrical drive signals applied at a speaker input locus to effect sound-producing movement by the audio element. Method 100 continues with the step of, in no particular order:(1) providing an amplifier unit having an amplifier input locus and an amplifier output locus; the amplifier output locus being coupled with the speaker input locus for applying the electrical drive signals as indicated by a block 104; and (2) providing a feedback circuit coupling at least one of the amplifier output locus and the speaker input locus with the amplifier input locus, as indicated by a block 106. The feedback circuit includes: [a] a monitoring unit coupled with at least one of the amplifier output locus and the speaker input locus; and [b] a processing unit coupled with the monitoring unit, with an input locus of the amplifier unit and with a signal source providing input signals representative of an audio input.

Method 100 continues with the step of operating the amplifier unit to generate the electrical drive signals, as indicated by a block 108. Method 100 continues with the step of operating the monitoring unit to generate indicating signals representing selected parameters associated with signals present at the speaker input locus, as indicated by a block 110. Method 100 continues with the step of operating the processing unit to combine the input signals with the indicating signals to generate a modified input signal for use by the amplifier unit in generating the electrical drive signals, as indicated by a block 112. The modified input signal includes at least one factor relating to velocity of the audio element while effecting the sound-producing movement. Method 100 terminates at an END locus 114.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

We claim:

1. An audio speaker system including an apparatus for controlling an amplifier device in driving an audio speaker unit; said speaker unit including an audio element effecting sound-producing movement in response to an applied electrical input signal; said speaker unit having a resistance and a force factor; the apparatus comprising:
(a) a measuring unit coupled between said amplifier device and said speaker unit; said measuring unit obtaining measurements of selected parameters of signals between said amplifier device and said speaker unit; and
(b) a processing device coupled with said measuring unit and with an audio signal device; said processing device receiving input signals from said audio signal device and receiving said measurements from said measuring unit; said processing unit combining said input signals and said measurements to generate a modified input signal for use by said amplifier device in effecting said driving said audio speaker unit, said modified input signal including at least one factor relating to velocity of said audio element while effecting said sound-producing movement; efficiency of said speaker unit being improved by inversely varying said resistance and said force factor with respect to each other.

2. An audio speaker system including an apparatus for controlling an amplifier device in driving an audio speaker unit as recited in claim 1 wherein said selected parameters include voltage applied by said amplifier device to said speaker unit.

3. An audio speaker system including an apparatus for controlling an amplifier device in driving an audio speaker unit as recited in claim 1 wherein said speaker unit includes a voice coil unit and wherein said selected parameters include current in said voice coil unit.

4. An audio speaker system including an apparatus for controlling an amplifier device in driving an audio speaker unit as recited in claim 3 wherein said selected parameters include voltage applied by said amplifier device to said speaker unit.

5. An audio speaker system including an apparatus for controlling an amplifier device in driving an audio speaker unit as recited in claim 1 wherein said measurements and said input signals are digitized for use by said processing device and said modified input signal is embodied in an analog signal; said processing device being embodied in a digital signal processor device effecting said combining using digital combining.

6. An audio speaker system including an apparatus for controlling an amplifier device in driving an audio speaker unit as recited in claim 1 wherein said processing device effects said combining using at least some software, and wherein said at least some software provides a scaling factor for use in effecting said combining, said scaling factor being selected to reduce damping output of said speaker unit.

7. An audio speaker system including an apparatus for controlling an amplifier device in driving an audio speaker unit as recited in claim 4 wherein said processing device effects said combining using at least some software, and wherein said at least some software provides a scaling factor for use in effecting said combining, said scaling factor being selected to reduce damping output of said speaker unit.

8. An audio speaker system including an apparatus for controlling driving of an audio speaker device; said speaker device including an audio element; said speaker device being driven by electrical drive signals applied at a speaker input locus to effect sound-producing movement by said audio element; said speaker device having a resistance and a force factor; the apparatus comprising:
(a) an amplifier unit having an amplifier input locus and an amplifier output locus; said amplifier unit generating said electrical drive signals; said amplifier output locus being coupled with said speaker input locus for applying said electrical drive signals; and
(b) a feedback circuit coupling at least one of said amplifier output locus and said speaker input locus with said amplifier input locus; said feedback circuit comprising:
(1) a monitoring unit coupled with at least one of said amplifier output locus and said speaker input locus; said monitoring unit generating indicating signals representing selected parameters associated with signals present at said speaker input locus; and
(2) a processing unit coupled with said monitoring unit, with an input locus of said amplifier unit and with a signal source providing input signals representative of an audio input; said processing unit combining said input signals with said indicating signals to generate a modified input signal for use by said amplifier unit in generating said electrical drive signals; said modified input signal including at least one factor relating to velocity of said audio element while effecting said sound-producing movement;
efficiency of said speaker device being improved by inversely varying said resistance and said force factor with respect to each other.

9. An audio speaker system including an apparatus for controlling driving of an audio speaker device as recited in claim 8 wherein said selected parameters include voltage extant between said amplifier unit and said speaker device.

10. An audio speaker system including an apparatus for controlling driving of an audio speaker device as recited in claim 8 wherein said speaker device includes a voice coil unit and wherein said selected parameters include current applied to said voice coil unit.

11. An audio speaker system including an apparatus for controlling driving of an audio speaker device as recited in claim 10 wherein said selected parameters include voltage extant between said amplifier unit and said speaker device.

12. An audio speaker system including an apparatus for controlling driving of an audio speaker device as recited in claim 8 wherein said indicating signals and said input signals are digitized for use by said processing unit and said modified input signal is embodied in an analog signal; said processing unit being embodied in a digital signal processor device effecting said combining using digital combining.

13. An audio speaker system including an apparatus for controlling driving of an audio speaker device as recited in claim 8 wherein said processing unit effects said combining using at least some software, and wherein said at least some software provides a scaling factor for use in effecting said combining, said scaling factor being selected to damp output of said speaker device.

14. An audio speaker system including an apparatus for controlling driving of an audio speaker device as recited in claim 11 wherein said processing unit effects said combining using at least some software, and wherein said at least some software provides a scaling factor for use in effecting said combining, said scaling factor being selected to reduce damping output of said speaker device.

15. A method for controlling driving of an audio speaker device; said speaker device including an audio element; said speaker device being driven by electrical drive signals applied at a speaker input locus to effect sound-producing movement by said audio element; said speaker device having a resistance and a force factor; the method comprising the steps of:
(a) in no particular order:
(1) providing an amplifier unit having an amplifier input locus and an amplifier output locus; said amplifier output locus being coupled with said speaker input locus for applying said electrical drive signals; and
(2) providing a feedback circuit coupling at least one of said amplifier output locus and said speaker input locus with said amplifier input locus; said feedback circuit comprising: [a] a monitoring unit coupled with at least one of said amplifier output locus and said speaker input locus; and [b] a processing unit coupled with said monitoring unit, with an input locus of said amplifier unit and with a signal source providing input signals representative of an audio input;
(b) operating said amplifier unit to generate said electrical drive signals;
(c) operating said monitoring unit to generate indicating signals representing selected parameters associated with signals present at said speaker input locus;
(d) operating said processing unit to combine said input signals with said indicating signals to generate a modified input signal for use by said amplifier unit in generating said electrical drive signals; said modified input signal including at least one factor relating to velocity of said audio element while effecting said sound-producing movement; and
(e) improving efficiency of said speaker device by inversely varying said resistance and said force factor with respect to each other.

16. A method for controlling driving of an audio speaker device as recited in claim 15 wherein said speaker device includes a voice coil unit and wherein said selected parameters include voltage extant between said amplifier unit and said speaker device and include current applied to said voice coil unit.

17. A method for controlling driving of an audio speaker device as recited in claim 15 wherein said indicating signals and said input signals are digitized for use by said processing unit and said modified input signal is embodied in an analog signal; said processing unit being embodied in a digital signal processor device effecting said combining using digital combining.

18. A method for controlling driving of an audio speaker device as recited in claim 15 wherein said processing unit effects said combining using at least some software, and wherein said at least some software provides a scaling factor for use in effecting said combining, said scaling factor being selected to damp output of said speaker device.

19. A method for controlling driving of an audio speaker device as recited in claim 17 wherein said processing unit effects said combining using at least some software, and wherein said at least some software provides a scaling factor for use in effecting said combining, said scaling factor being selected to reduce damping output of said speaker device.

20. An audio speaker system including an audio element effecting sound-producing movement in response to an applied electrical input signal; said audio element having a resistance and a force factor; efficiency of said audio element being improved by inversely varying said resistance and said force factor with respect to each other.

21. An audio speaker system including an audio element effecting sound-producing movement in response to an applied electrical input signal as recited in claim 20 wherein the system includes an apparatus for controlling an amplifier device in driving said audio element; the apparatus comprising:
(a) a measuring unit coupled between said amplifier device and said audio element; said measuring unit obtaining measurements of selected parameters of signals between said amplifier device and said audio element; and
(b) a processing device coupled with said measuring unit and with an audio signal device; said processing device receiving input signals from said audio signal device and receiving said measurements from said measuring unit; said processing unit combining said input signals and said measurements to generate a modified input signal for use by said amplifier device in effecting said driving said audio element; said modified input signal including at least one factor relating to velocity of said audio element while effecting said sound-producing movement.

22. An audio speaker system including an audio element effecting sound-producing movement in response to an applied electrical input signal as recited in claim 21 wherein said selected parameters include voltage applied by said amplifier device to said audio element.

23. An audio speaker system including an audio element effecting sound-producing movement in response to an applied electrical input signal as recited in claim 21 wherein said audio element includes a voice coil unit and wherein said selected parameters include current in said voice coil unit.

24. An audio speaker system including an audio element effecting sound-producing movement in response to an applied electrical input signal as recited in claim 22 wherein said audio element includes a voice coil unit and wherein said selected parameters include current in said voice coil unit.

25. An audio speaker system including an audio element effecting sound-producing movement in response to an applied electrical input signal as recited in claim 21 wherein said measurements and said input signals are digitized for use by said processing device and said modified input signal is embodied in an analog signal; said processing device being embodied in a digital signal processor device effecting said combining using digital combining.

26. An audio speaker system including an audio element effecting sound-producing movement in response to an applied electrical input signal as recited in claim 25 wherein said processing device effects said combining using at least some software, and wherein said at least some software provides a scaling factor for use in effecting said combining, said scaling factor being selected to reduce damping output of said audio element.

27. An audio speaker system including an audio element effecting sound-producing movement in response to an applied electrical input signal as recited in claim 24 wherein said measurements and said input signals are digitized for use by said processing device and said modified input signal is embodied in an analog signal; said processing device being embodied in a digital signal processor device effecting said combining using digital combining.

28. An audio speaker system including an audio element effecting sound-producing movement in response to an applied electrical input signal as recited in claim 27 wherein said processing device effects said combining using at least some software, and wherein said at least some software provides a scaling factor for use in effecting said combining, said scaling factor being selected to reduce damping output of said audio element.
